(19) United States
(12) Patent Application Publication
(10) Pub. No.: US 2025/0149415 A1
(43) Pub. Date: May 8, 2025

(54) PACKAGING STRUCTURE AND METHOD FOR FORMING THE SAME

(71) Applicant: JCET Group Co., LTD., Jiangyin (CN)

(72) Inventors: Yun GAO, Jiangyin (CN); Rong FAN, Jiangyin (CN)

(21) Appl. No.: 18/913,258

(22) Filed: Oct. 11, 2024

(30) Foreign Application Priority Data
Nov. 3, 2023 (CN) 202311461275.0

(51) Int. Cl. H01L 23/498; H01L 21/48; H01L 21/56; H01L 23/00; H01L 23/31; H01L 23/367; H01L 25/065

(52) U.S. Cl. CPC H01L 23/49811; H01L 21/4853; H01L 21/565; H01L 23/3121; H01L 23/3672; H01L 23/49838; H01L 24/48; H01L 24/96; H01L 24/97; H01L 24/32; H01L 24/73; H01L 25/0655; H01L 2224/32225; H01L 2224/48091; H01L 2224/48245; H01L 2224/73265; H01L 2224/96; H01L 2224/97; H01L 2924/1815

(57) ABSTRACT

The present disclosure relates to a packaging structure and a method for forming the same. The packaging structure includes a frame, a chip, a pin structure, and a second molding layer. The frame includes a first molding layer and a base island running through the first molding layer along a first direction. The frame has an upper surface and a lower surface disposed opposed along the first direction. The chip is disposed on the lower surface of the frame and electrically connected to the base island. The pin structure is disposed on the lower surface of the frame and includes a plurality of pin rings nested in sequence, each of which includes a plurality of pins disposed around an outer circumference of the chip. The pins are electrically connected to the chip. The second molding layer covers the lower surface of the frame, the chip, and the pin structure.

### CROSS-REFERENCE TO RELATED APPLICATIONS

This application claims the benefit of priority to Chinese Application No. 202311461275.0, filed on Nov. 3, 2023, which is hereby incorporated by reference in its entirety.

### TECHNICAL FIELD

The present disclosure relates to the technical field of integrated circuit manufacturing and particularly relates to a packaging structure and a method for forming the same.

### BACKGROUND

QFN (Quad Flat No-leads Package) is a commonly used packaging method. The QFN packaging method has the advantages of good electrical and thermal performance, small size, lightweight, low development cost, etc., and is suitable for application in high-density printed circuit boards of mobile phones, digital cameras, PDAs, and other portable small electronic devices. The QFN packaging structure includes a base island and a ring of pins disposed around the outer circumference of the base island.

### SUMMARY

According to some embodiments, the present disclosure provides a packaging structure, including a frame, a chip, a pin structure, and a second molding layer. The frame includes a first molding layer and a base island running through the first molding layer along a first direction. The frame has an upper surface and a lower surface disposed opposed along the first direction. The chip is disposed on the lower surface of the frame and electrically connected to the base island. The pin structure is disposed on the lower surface of the frame and includes at least one pin ring. Each of the pin ring includes a plurality of pins disposed around an outer circumference of the chip. The pins are electrically connected to the chip. The second molding layer covers the lower surface of the frame, the chip, and the pin structure.

In some embodiments, the pin structure includes a plurality of pin rings nested in sequence.

In some embodiments, the frame further includes a connection structure including a plurality of connection rings nested in sequence. The plurality of connection rings correspond one-to-one to the plurality of pin rings. Each of the connection rings includes a plurality of connection islands disposed around an outer circumference of the base island. The plurality of connection islands in each of the connection rings is connected in one-to-one correspondence with the plurality of pins in the pin rings corresponding thereto.

In some embodiments, the connection structure further includes a connection piece disposed between the two adjacent connection rings for electrically connecting the connection islands in the two adjacent connection rings.

In some embodiments, the pin includes a welding part disposed on the lower surface of the frame and welded to the connection island, and a lead-out part disposed on a side of the welding part facing away from the frame. The lead-out part is electrically connected to the welding part, and the width of the welding part at least along the second direction is greater than the width of the lead-out part along the second direction intersecting with the first direction.

In some embodiments, the packaging structure further includes a connection wire disposed within the second molding layer. One end of the connection wire is electrically connected to the chip, and the other end is electrically connected to a portion of the welding part protruding from the lead-out part in the second direction.

In some embodiments, for any adjacent two of the pin rings, the pins in one of the pin rings are arranged staggered from the pins in the other pin ring.

In some embodiments, the packaging structure further includes a sawing street running successively in the first direction through the frame and the second molding layer, such that a gap is formed between an edge of the sawing street and the pin located in the outermost pin ring in the pin structure.

In some embodiments, the packaging structure further includes a heat dissipation structure disposed on the upper surface of the frame. The projection of the heat dissipation structure on the upper surface of the frame covers at least a portion of the base island.

According to other embodiments, the present disclosure also provides a method for forming a packaging structure. A frame is formed. The frame includes a first molding layer and a base island running through the first molding layer along a first direction. The frame has an upper surface and a lower surface disposed opposed along the first direction. A pin structure and a chip on the lower surface of the frame are connected. The chip is electrically connected to the base island. The pin structure includes at least one pin ring. Each of the pin rings includes a plurality of pins disposed around an outer circumference of the chip. The pins are electrically connected to the chip. A second molding layer is formed on the lower surface of the frame. The second molding layer covers the chip and the pin structure.

In some embodiments, the pin structure is multiple pin rings, and the multiple pin rings are nested in sequence.

In some embodiments, to form the frame, a base island and a connection structure are formed. The connection structure includes a plurality of connection rings nested in sequence, and each of the connection rings includes a plurality of connection islands disposed around an outer circumference of the base island. To form the frame, the first molding layer that molds the base island and the connection structure is formed. The connection island and the base island both are exposed to the lower surface of the frame.

In some embodiments, to connect the pin structure and the chip on the lower surface of the frame, a plurality of pin rings are connected corresponding one-to-one to a plurality of connection rings on the lower surface of the frame. Each pin ring includes a plurality of pins connected in one-to-one correspondence with a plurality of connection islands in the connection rings corresponding thereto. In some embodiments, to connect the pin structure and the chip on the lower surface of the frame, the base island and the chip on the lower surface of the frame are connected.

In some embodiments, to connect the plurality of pin rings corresponding one-to-one to a plurality of connection rings on the lower surface of the frame, a plurality of pins corresponding one-to-one to a plurality of connection islands in the connection structure are formed using a punching process. The pins include a welding part and a lead-out part electrically connected to each other, and the width of the welding part at least along the second direction is greater than the width of the lead-out part along the second direction intersecting with the first direction. In some embodiments, to connect the plurality of pin rings corresponding one-to-one to a plurality of connection rings on the lower surface of the frame, the welding parts of a plurality of pins are welded one by one to a plurality of connection islands, such that the lead-out parts and the connection islands are disposed on opposite sides of the welding parts along the first direction.

In some embodiments, after connecting the pin structure and the chip on the lower surface of the frame, a connection wire is formed. One end of the connection wire is electrically connected to the chip, and the other end of the connection wire is electrically connected to a portion of the welding part protruding from the lead-out part in the second direction.

In some embodiments, the frame includes a plurality of base islands arranged at intervals in the second direction, and the first molding layer successively molds a plurality of base islands. A plurality of chips are connected to a plurality of base islands, respectively, and a plurality of pin structures independent from each other are arranged one by one on an outer circumference of a plurality of chips. One of the base islands, the chip connected to the base island and one of the pin structures disposed around the outer circumference of the chip serve as a package unit.

In some embodiments, a sawing street between adjacent package units is defined, such that a gap is formed between an edge of the sawing street and the pin disposed in the outermost pin ring of the package units adjacent thereto, and the package units are cut along the sawing street to form a plurality of independent package units. Each of the independent package units serves as a packaging structure.

In some embodiments, a heat dissipation structure is formed on the upper surface of the frame. A projection of the heat dissipation structure on the upper surface of the frame covers at least a portion of the base island.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 is a top view schematic diagram of a packaging structure, according to some embodiments of the present disclosure;

FIG. 2 is a bottom view schematic diagram of a packaging structure, according to some embodiments of the present disclosure;

FIG. 3 is a sectional schematic diagram of a packaging structure, according to some embodiments of the present disclosure;

FIG. 4 is a flowchart of a method for forming a packaging structure, according to some embodiments of the present disclosure; and

FIGS. 5-10 are schematic diagrams of the main process structures of the method in the process for forming the packaging structure, according to some embodiments of the present disclosure.

### DETAILED DESCRIPTION

The specific embodiments of the present disclosure are described in detail below in conjunction with the accompanying drawings. In detailing the embodiments of the present disclosure, the schematic diagrams will not be locally enlarged according to the general scale for the convenience of illustration, and the schematic diagrams are only examples, which should not limit the scope of protection of the present disclosure herein. In addition, the three-dimensional spatial dimensions of length, width, and depth should be included in the actual production.

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be disposed between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnects are formed) and one or more dielectric layers.

It should be noted that the terms “comprising,” “including,” and “having,” and their variations, referred to in the present disclosure are intended to cover non-exclusive inclusion. The terms “first,” “second,” etc. are used to distinguish between similar objects and need not be used to describe a specific order or sequence unless the context clearly indicates that the data used in this way can be interchanged in appropriate circumstances. In addition, the embodiments and the features in the embodiments in the present disclosure may be combined with each other without conflict. Furthermore, in the above explanation, descriptions of well-known components and techniques have been omitted to avoid unnecessarily confusing the concepts of the present disclosure. In the various embodiments below, each embodiment focuses on the differences from other embodiments, and the same/similar parts between various embodiments can be referenced to (or referred to) each other.

QFN packaging structure, however, has a small number of pins and relatively sparse arrangement due to the effect of cutting limitations, which limits the further improvement of the integration of the QFN packaging structure. Moreover, due to the small number of pins and the relatively sparse arrangement, the length of the wiring required for connecting the pins to the chip is longer and more difficult, and results in the complexity of the internal circuitry of the QFN packaging structure, thereby reducing the productivity of the QFN packaging structure. In addition, the QFN packaging structure dissipates heat through the Printed Circuit Board (PCB), and the dissipated heat amount is limited, which easily leads to the accumulation of heat inside the QFN packaging structure, thereby easily causing damage to the QFN packaging structure, and ultimately leading to the degradation of the performance of the QFN packaging structure.

Therefore, how to simplify the manufacturing process of packaging structure and improve the product yield of packaging structure is an urgent technical problem that needs to be solved at present.

To solve one of more of the above-mentioned technical problems, the present disclosure provides a packaging structure and a method for forming the same to simplify the manufacturing process of the packaging structure and improve the product yield of the packaging structure. In the packaging structure and the method for forming the same provided by the present disclosure, a plurality of pin rings are nested in sequence around the outer circumference of the chip. Each pin ring includes a plurality of pins disposed around the outer circumference of the chip, and the pins are electrically connected to the chip, thereby increasing the number and density of pins in the packaging structure, which, on one hand, is helpful to reduce the difficulty in connecting the chip with the pins, such as the length of the connection wire between the chip and the pins, thereby simplifying the manufacturing process of the packaging structure and improving the manufacturing yield of the packaging structure. On the other hand, the increase in the number of pins enables more inputs/outputs to be realized and is helpful in increasing the integration degree of the packaging structure. Moreover, the base island in the present disclosure runs through the first molding layer in the frame, and the chip and the pin structure are both disposed on the lower surface of the frame, so that heat may be dissipated from the base island on the upper surface of the frame, thereby reducing the heat accumulation inside the base island, thus improving the heat dissipation performance of the packaging structure.

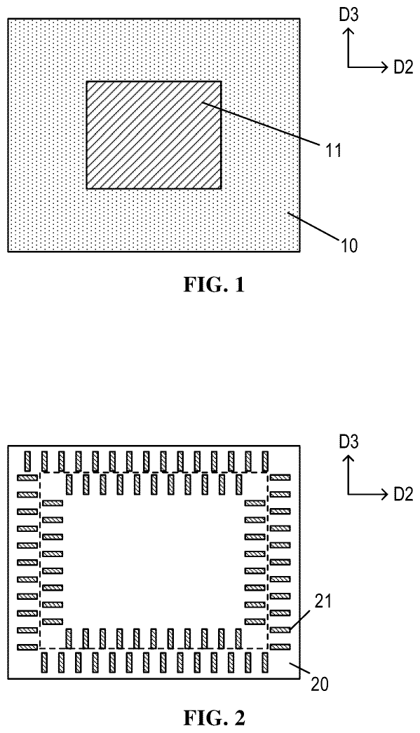

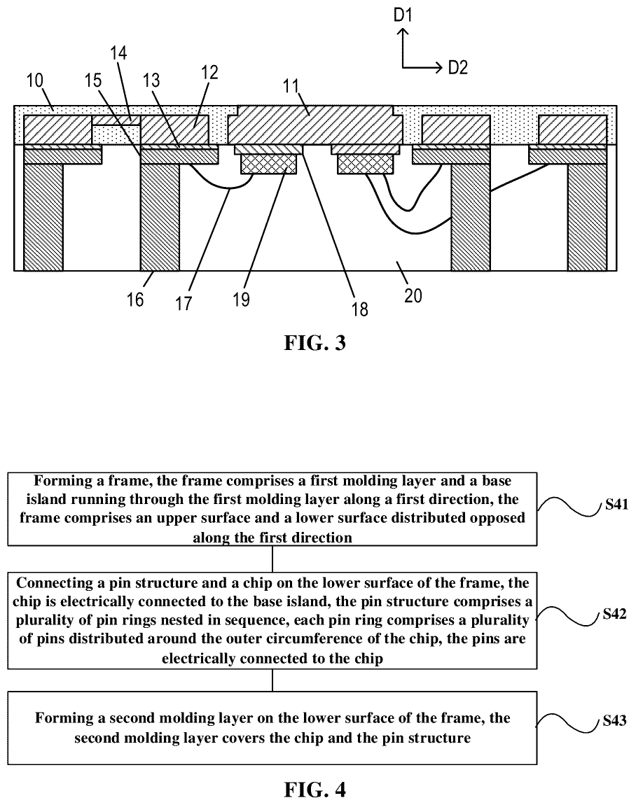

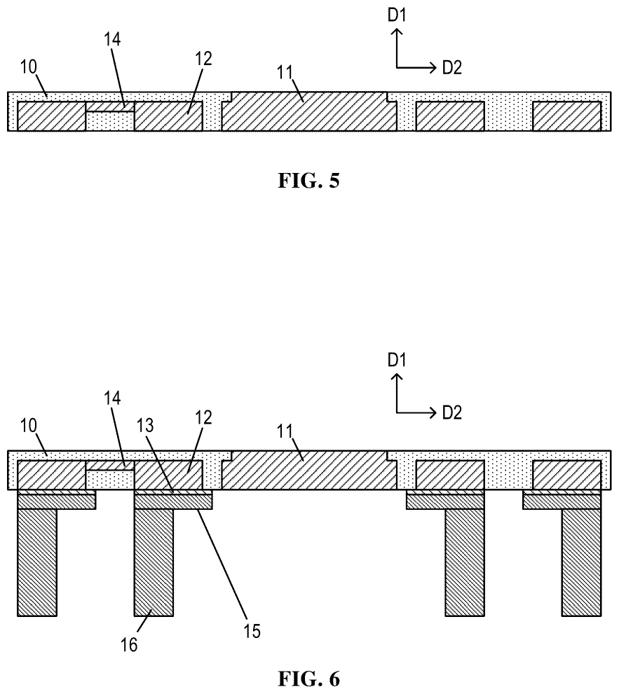

Some embodiments of the present disclosure provide a packaging structure. FIG. 1 is a top view schematic diagram of the packaging structure in some embodiments of the present disclosure, FIG. 2 is a bottom view schematic diagram of the packaging structure in some embodiments of the present disclosure, and FIG. 3 is a sectional schematic diagram of the packaging structure in some embodiments of the present disclosure. As shown in FIGS. 1-3, the packaging structure includes a frame including a first molding layer 10 and a base island 11 running through the first molding layer 10 along a first direction D1. The frame has an upper surface and a lower surface disposed opposed along the first direction D1. The packaging structure also includes a chip 19 disposed on the lower surface of the frame and electrically connected to the base island 11. The chip 19 may include a logic chip or a memory chip. In some embodiments, the logic chip may include a gate array, a unit substrate array, an embedded array, a structured application-specific integrated circuit (ASIC), a field programmable gate array (FPGA), a complex programmable logic device (CPLD), a central processing unit (CPU), a microprocessor unit (MPU), a microcontroller unit (MCU), a logic integrated circuit (IC), an application processor (AP), a display driver IC (DDI), a radio frequency (RF) chip, a power source chip, or a complementary metal oxide semiconductor (CMOS) image sensor. In some embodiments, the memory chip may include a volatile memory chip (e.g., dynamic random-access memory (DRAM) or static RAM (SRAM)) or a non-volatile memory chip (e.g., flash memory (Flash), a phase-change RAM (PRAM), a magneto-resistive RAM (MRAM), a ferroelectric RAM (FeRAM), or a resistive RAM (ReRAM)). For example, the memory chip may include a high bandwidth memory (HBM) including a DRAM chip.

The packaging structure further includes a pin structure disposed on the lower surface of the frame and including a plurality of pin rings nested in sequence, each of which includes a plurality of pins 21 disposed around the outer circumference of the chip 19. The pins 21 are electrically connected to the chip 19. The packaging structure further includes a second molding layer 20, which covers the lower surface of the frame, the chip 19, and the pin structure.

For example, as shown in FIGS. 1-3, the first molding layer 10 covers the sidewalls of the base island 11, the bottom surface of the base island 11 is exposed to the bottom surface of the first molding layer 10, and the top surface of the base island 11 is exposed to the top surface of the first molding layer 10. The chip 19 is disposed on the lower surface of the frame and is electrically connected to the bottom surface of the base island 11, and the base island 11 is configured to transmit control signals to the chip 19. The pin structure is disposed on the lower surface of the frame and includes a plurality of pin rings nested in sequence, each of which includes a plurality of pins 21 disposed around the outer circumference of the chip 19, so that the number of the pins 21 in the packaging structure for electrical connection to the chip 19 is substantially increased, thereby enabling more inputs/outputs and contributing to the improvement of the integration degree of the packaging structure. The pin structure includes a plurality of pin rings, which are nested in sequence along a direction parallel to the lower surface of the frame (e.g., the second direction D2 and the third direction D3 in FIG. 2), so that the signal of the chip 19 can be jointly led out or introduced into the chip 19 through the pins 21 in the plurality of pin rings, thereby shortening the length of a single connection wire between the chip and the pins, and reducing the difficulty in wire-bonding the connection wire and realizing the simplification of the manufacturing process of the packaging structure. Since both the chip 19 and the pin structure are disposed below the base island 11, the base island 11 is able to dissipate heat from above, which reduces the heat accumulation inside the base island 11, thereby improving the heat dissipation performance of the packaging structure. “In an example, as shown in FIG. 2, the pin structure includes a first pin ring (shown in the dashed box in FIG. 2) disposed around the outer circumference of the chip 19 and a second pin ring disposed around the outer circumference of the first pin ring, thereby avoiding occupation of too much area in the packaging structure while increasing the number of pins and reducing the difficulty of the manufacturing process of the packaging structure. In an example, the material of the first molding layer 10 is the same as the material of the second molding layer 20 to reduce the manufacturing cost of the packaging structure.

In some embodiments, the frame further includes a connection structure including a plurality of connection rings nested in sequence. The plurality of connection rings correspond one-to-one to a plurality of pin rings, and each of the connection rings includes a plurality of connection islands 12 disposed around the outer circumference of the base island 11. The plurality of connection islands 12 in each of the connection rings and the plurality of pins 21 in the pin rings corresponding thereto are connected in one-to-one correspondence.

In an example, the connection structure and the base island 11 may be formed synchronously using the same material, thereby further simplifying the manufacturing process of the packaging structure. In an example, the materials of the connection structure and the base island 11 are both conductive materials, such as metallic copper. By arranging the connection island 12 in the frame, the pin 21 is fixed on the lower surface of the frame through the connection of the connection island 12 to the pin 21, thereby enhancing the stability of the connection between the pin 21 and the frame. In an example, the material of the connection structure and the material of the pins are both conductive materials, for example, metallic materials (e.g., copper), to simplify the process of connection between the pins and the connection structure while enhancing the stability of the connection between the pins 21 and the frame, by welding the pins to the connection island 12 in the connection structure at the first connection layer 13. In an example, the material of the first connection layer 13 is a conductive solder, such as silver colloid.

In some embodiments, the connection structure further includes a connection piece 14, which is disposed between the two adjacent connection rings for electrically connecting the connection island 12 in the two adjacent connection rings.

Specifically, by arranging the connection piece 14 electrically connecting the connection island 12 in the two adjacent connection rings in the connection structure, the signals of the chip 19 are able to be led out through the connection island 12 and the connection piece 14, which, on one hand, shortens the length of a single connection wire between the chip and the pin, thereby reducing the difficulty in wire-bonding the connection wire between the chip 19 and the pin 21 and realizing the simplification of the manufacturing process of the packaging structure. On the other hand, by arranging the connection island 12 and the connection piece 14 in the frame, it is able to indirectly realize the electrical connection between the pins 21 in adjacent pin rings in the frame, thereby simplifying the process of connection between the pins 21.

In some embodiments, the pin 21 includes a welding part 15 disposed on the lower surface of the frame and welded to the connection island 12, and a lead-out part 16 disposed on a side of the welding part 15 facing away from the frame. The lead-out part 16 is electrically connected to the welding part 15. The width of the welding part 15 at least along the second direction D2 is greater than the width of the lead-out part 16 along the second direction D2, which intersects with the first direction D1.

In some embodiments, the packaging structure further includes a connection wire 17 disposed within the second molding layer 20. One end of the connection wire 17 is electrically connected to the chip 19, and the other end is electrically connected to a portion of the welding part 15 protruding from the lead-out part 16 in the second direction D2.

Specifically, as shown in FIGS. 1-3, the pin 21 includes the welding part 15 welded to the connection island 12 via the first connection layer 13 and the lead-out part 16 disposed on the side of the welding part 15 facing away from the connection island 12. The lead-out part 16 is electrically connected to the welding part 15. The width of the welding part 15 (e.g., the width of the welding part 15 along the second direction D2) is greater than the width of the lead-out part 16 (e.g., the width of the lead-out part 16 along the second direction D2), such that the welding part 15 protrudes from the lead-out part 16 at least along the second direction D2, which, on one hand, enables an increase of the connection area between the pins 21 and the connection structure, thereby further enhancing the stability of the connection between the pins 21 and the connection structure. On the other hand, it is also helpful to increase the process window for forming the connection wire 17, which further reduces the process difficulty of forming the connection wire 17. In an example, the connection wire 17 may be a gold wire or a copper wire.

In some embodiments, for any two adjacent pin rings, the pins 21 in one of the pin rings are arranged staggered from the pins 21 in the other the pin ring, thereby reducing the parasitic capacitance effect between the pins 21 in the two adjacent pin rings, while further simplifying the manufacturing process of the pin structure and reducing the process difficulty in forming the connection wire 17.

In some embodiments, the packaging structure further includes a sawing street running successively in the first direction D1 through the frame and the second molding layer 20, such that a gap is formed between an edge of the sawing street and the pins 21 disposed in the outermost pin ring in the pin structure. By having a gap between the edge of the sawing street and the pins 21 in the pin ring located in the outermost pin ring of the pin structure, after forming a plurality of packaging structures as a whole by a packaging process, it is possible to avoid cutting the pin structure when cutting the whole to form a plurality of separate packaging structures along the sawing street, and to avoid metal burrs remaining at the edge of the packaging structures after cutting, and also to reduce wear and tear on the cutting tools (e.g., cutting knives), thereby further reducing the cost of the packaging process.

In some embodiments, the packaging structure further includes a heat dissipation structure disposed on the upper surface of the frame. The projection of the heat dissipation structure on the upper surface of the frame covers at least a portion of the base island 11.

Specifically, the chip 19 is connected to the lower surface of the frame via a second connection layer 18, and the chip 19 is electrically connected to the base island 11. Since both the pin structure and the chip 19 are located on the lower surface of the frame, a heat dissipation structure, such as water cooling or a heat sink, can be arranged on the top surface of the base island 11 to improve the heat dissipation performance of the packaging structure (e.g., the heat dissipation performance of the base island 11 in the packaging structure).

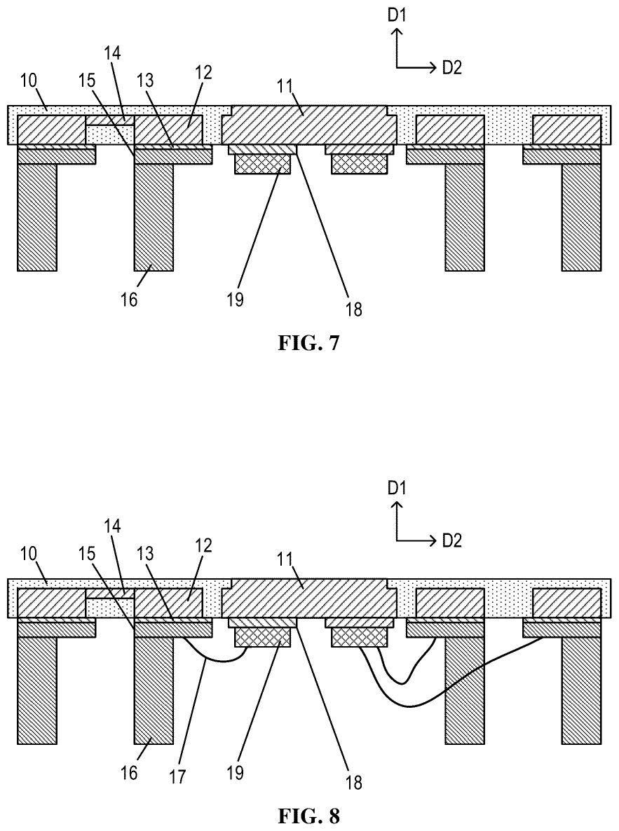

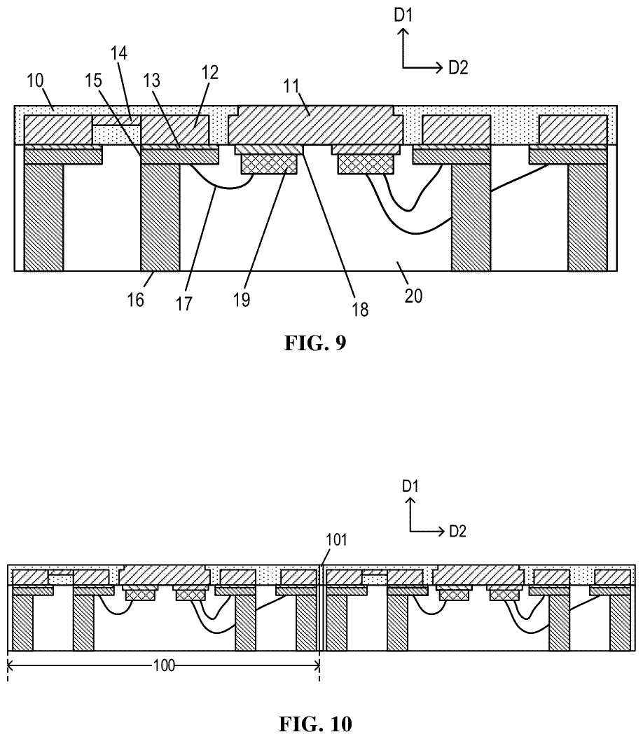

In some embodiments of the present disclosure, a method for forming a packaging structure is also provided. FIG. 4 is a flowchart of a method for forming the packaging structure in some embodiments of the present disclosure, FIGS. 5-10 are schematic diagrams of the main process structures of some embodiments of the present method in the process for forming the packaging structure. The schematic diagram of the packaging structure formed in some embodiments can be seen in FIGS. 1-3. As shown in FIGS. 4-10, the method for forming the packaging structure includes the following operations.

At operation S41, a frame is formed. The frame includes a first molding layer 10 and a base island 11 running through the first molding layer 10 along a first direction D1. The frame has an upper surface and a lower surface disposed opposed along the first direction D1, as shown in FIG. 5.

At operation S42, a pin structure and a chip 19 on the lower surface of the frame are connected. The chip 19 is electrically connected to the base island 11. The pin structure includes a plurality of pin rings nested in sequence. Each of the pin rings includes a plurality of pins 21 disposed around the outer circumference of the chip 19. The pins 21 are electrically connected to the chip 19, as shown in FIG. 8.

At operation S43, a second molding layer 20 is formed on the lower surface of the frame. The second molding layer 20 covers the chip 19 and the pin structure, as shown in FIG. 9.

In some embodiments, the operation of forming the frame includes the following. A base island 11 and a connection structure are formed. The connection structure includes a plurality of connection rings nested in sequence, each of which includes a plurality of connection islands 12 disposed around the outer circumference of the base island 11. The first molding layer 10 that molds the base island 11 and the connection structure is formed. The frame includes the base island 11, the connection structure, and the first molding layer 10 is formed. The connection island 12 and the base island 11 are both exposed to the lower surface of the frame.

In some embodiments, the operations of connecting the pin structure and the chip 19 on the lower surface of the frame include the following. A plurality of pin rings corresponding one-to-one to a plurality of connection rings on the lower surface of the frame are connected. Each pin ring includes a plurality of pins 21 connected in one-to-one correspondence with a plurality of connection islands 12 in the connection rings corresponding thereto. The base island 11 and the chip 19 on the lower surface of the frame are connected.

In some embodiments, the operations of connecting a plurality of pin rings corresponding one-to-one to a plurality of connection rings on the lower surface of the frame include the following.

A plurality of pins 21 corresponding one-to-one to a plurality of connection islands 12 in the connection structure are formed using a punching process. The pins 21 include a welding part 15 and a lead-out part 16 electrically connected to each other, and the width of the welding part 15 at least along the second direction D2 is greater than the width of the lead-out part 16 along the second direction D2, which intersects with the first direction D1. The welding parts 15 of a plurality of pins 21 are welded one by one to the plurality of connection islands 12, such that the lead-out parts 16 and the connection islands 12 are disposed on opposite sides of the welding parts 15 along the first direction D1.

In some embodiments, after connecting the pin structure and the chip 19 on the lower surface of the frame, a connection wire 17 is formed. One end of the connection wire 17 is electrically connected to the chip 19, and the other end is electrically connected to a portion of the welding part 15 protruding from the lead-out part 16 along the second direction D2.

By way of example, the frame including the base island 11, the connection structure, and the first molding layer 10 can be formed by a compressing, exposure, development, electroplating, stripping and encapsulation process, and a connection piece 14 is present within the frame. The connection piece 14 is located between two adjacent connection rings and electrically connects the connection islands 12 in the two adjacent connection rings, as shown in FIG. 5. Next, the pins 21 including the welding part 15 and the lead-out part 16 are formed using a punching process, and a plurality of pins 21 are connected one by one to the surface of a plurality of connection islands 12 by the first connection layer 13, as shown in FIG. 6. Afterwards, the chip 19 is then connected to the lower surface of the frame by the second connection layer 18, and the chip 19 is made electrically connected to the base island 11, as shown in FIG. 7. Then, the connection wire 17 connecting the chip 19 to the pin 21 is formed, as shown in FIG. 8. Next, the second molding layer 20 is formed at least on the lower surface of the frame by a molding process, and the second molding layer 20 covers the chip 19 and the pin structure, as shown in FIG. 9.

In some embodiments, the frame includes a plurality of base islands 11 spaced apart along the second direction D2, and the first molding layer 10 successively molds the plurality of base islands 11. A plurality of chips 19 are connected to a plurality of base islands 11, respectively, and a plurality of pin structures are independent from each other and arranged one by one on the outer circumference of a plurality of chips 19. One of the base islands 11, the chip 19 connected to the base island 11, and one of the pin structures disposed around the outer circumference of the chips 19 serve as a packaging unit 100.

A sawing street 101 between adjacent packaging units 100 is defined. There is a gap between an edge of the sawing street 101 and the pins 21 disposed in the outermost pin ring of the packaging units 100 adjacent thereto. The packaging units 100 are cut along the sawing street 101 to form a plurality of independent packaging units 100, each of which serves as a packaging structure.

By way of example, a plurality of packaging units 100 are formed as shown in FIG. 10. The plurality of packaging units 100 are arranged at least along the second direction D2, and adjacent packaging units 100 are connected to each other by the first molding layer 10 and the second molding layer 20. The pin structures between adjacent packaging units 100 are independent of each other, i.e., the pin structures in adjacent package units 100 are isolated from each other by the sawing street and the second molding layer 20. When cutting along the sawing street 101, the pin structures will not be cut, thereby avoiding burrs generated by cutting the pins, and also reducing wear and tear on the cutting tools (e.g., cutting knives), thereby further reducing the cost of the packaging process.

In some embodiments, the method further includes forming a heat dissipation structure on the upper surface of the frame. The projection of the heat dissipation structure on the upper surface of the frame covers at least a portion of the base island 11.

In the packaging structure and the method for forming the same provided by the present disclosure, a plurality of pin rings are arranged nested in sequence around the outer circumference of the chip. Each pin ring includes a plurality of pins disposed around the outer circumference of the chip, and the pins are electrically connected to the chip, thereby increasing the number and density of pins in the packaging structure, which, on one hand, is helpful to reduce the difficulty in connecting the chip with the pins, such as the length of the connection wire between the chip and the pins, thereby simplifying the manufacturing process of the packaging structure and improving the manufacturing yield of the packaging structure. On the other hand, the increase in the number of pins enables more inputs/outputs to be realized and is helpful in increasing the integration degree of the packaging structure. Moreover, the base island in the present disclosure runs through the first molding layer in the frame, and the chip and the pin structure are both disposed on the lower surface of the frame, which enables heat to be dissipated from the base island on the upper surface of the frame and reduces the heat accumulation inside the base island, thereby improving the heat dissipation performance of the packaging structure.

The foregoing is only some embodiments of the present disclosure, and it should be noted that for a person of ordinary skilled in the art, a number of improvements and variations may be made without departing from the principles of the present disclosure, and these improvements and variations should also be deemed to fall within the scope of protection of the present disclosure.

What is claimed is:

1. A packaging structure, comprising:
a frame comprising a first molding layer and a base island running through the first molding layer along a first direction, the frame having an upper surface and a lower surface disposed opposed along the first direction;
a chip disposed on the lower surface of the frame and electrically connected to the base island;
a pin structure disposed on the lower surface of the frame and comprising at least one pin ring, each of the pin ring comprising a plurality of pins disposed around an outer circumference of the chip, the pins being electrically connected to the chip; and
a second molding layer covering the lower surface of the frame, the chip, and the pin structure.

2. The packaging structure according to claim 1, wherein the pin structure comprises a plurality of pin rings nested in sequence.

3. The packaging structure according to claim 2, wherein the frame further comprises:
a connection structure comprising a plurality of connection rings nested in sequence, the plurality of connection rings corresponding one-to-one to the plurality of pin rings, each of the connection rings comprising a plurality of connection islands disposed around an outer circumference of the base island, the plurality of connection islands in each of the connection rings being connected in one-to-one correspondence with the plurality of pins in the pin rings corresponding thereto.

4. The packaging structure according to claim 3, wherein the connection structure further comprises a connection piece disposed between two adjacent connection rings of the connection rings for electrically connecting the connection islands in the two adjacent connection rings.

5. The packaging structure according to claim 3, wherein each of the pins comprises:
a welding part disposed on the lower surface of the frame and welded to the respective connection island; and
a lead-out part disposed on a side of the welding part facing away from the frame, the lead-out part being electrically connected to the welding part, a width of the welding part at least along a second direction being greater than the width of the lead-out part along the second direction intersecting with the first direction.

6. The packaging structure according to claim 5, further comprising:
a connection wire disposed within the second molding layer, one end of the connection wire being electrically connected to the chip and another end of the connection wire being electrically connected to a portion of the welding part protruding from the lead-out part in the second direction.

7. The packaging structure according to claim 2, wherein for any adjacent two of the pin rings, the pins in one of the pin rings are arranged staggered from the pins in the other pin ring.

8. The packaging structure according to claim 1, further comprising:
a sawing street running successively in the first direction through the frame and the second molding layer, such that a gap is formed between an edge of the sawing street and the pins disposed in an outermost pin ring in the pin structure.

9. The packaging structure according to claim 1, further comprising:
a heat dissipation structure disposed on the upper surface of the frame, wherein a projection of the heat dissipation structure on the upper surface of the frame covers at least a portion of the base island.

10. A method for forming a packaging structure, comprising:
forming a frame, the frame comprising a first molding layer and a base island running through the first molding layer along a first direction, the frame having an upper surface and a lower surface distributed opposed along the first direction;
connecting a pin structure and a chip on the lower surface of the frame, the chip being electrically connected to the base island, the pin structure comprising at least one pin ring, each of the pin ring comprising a plurality of pins disposed around an outer circumference of the chip, the pins being electrically connected to the chip; and
forming a second molding layer on the lower surface of the frame, the second molding layer covering the chip and the pin structure.

11. The method according to claim 10, wherein the pin structure is multiple pin rings, and the multiple pin rings are nested in sequence.

12. The method according to claim 11, wherein forming the frame comprises:
forming a base island and a connection structure, the connection structure comprising a plurality of connection rings nested in sequence, each of the connection rings comprising a plurality of connection islands disposed around the outer circumference of the base island; and
forming the first molding layer that molds the base island and the connection structure, the connection island and the base island both being exposed to the lower surface of the frame.

13. The method according to claim 12, wherein connecting the pin structure and the chip on the lower surface of the frame comprises:
connecting a plurality of pin rings corresponding one-to-one to a plurality of connection rings on the lower surface of the frame, each of the pin rings comprising a plurality of pins connected in one-to-one correspondence with a plurality of connection islands in the connection rings corresponding thereto; and
connecting the base island and the chip on the lower surface of the frame.

14. The method according to claim 13, wherein connecting the plurality of pin rings corresponding one-to-one to a plurality of connection rings on the lower surface of the frame comprises:
forming a plurality of pins corresponding one-to-one to a plurality of connection islands in the connection structure using a punching process, the pins comprising a welding part and a lead-out part electrically connected to each other, a width of the welding part at least along a second direction being greater than the width of the lead-out part along the second direction intersecting with the first direction; and
welding the welding parts of the pins one by one to a plurality of connection islands, such that the lead-out parts and the connection islands are disposed on opposite sides of the welding parts along the first direction.

15. The method according to claim 14, further comprising, after connecting the pin structure and the chip on the lower surface of the frame:
forming a connection wire, one end of the connection wire being electrically connected to the chip and another end of the connection wire being electrically connected to a portion of the welding part protruding from the lead-out part in the second direction.

16. The method according to claim 10, further comprising:
forming a heat dissipation structure on the upper surface of the frame, wherein a projection of the heat dissipation structure on the upper surface of the frame covers at least a portion of the base island.

17. A method for forming a packaging structure, comprising:
forming packaging units each comprising a base island, a chip connected to the base island, and a pin structure disposed around an outer circumference of the chip, wherein adjacent packaging units of the packaging units are connected to each other by a first molding layer and a second molding layer;
defining a sawing street between the adjacent packaging units; and
cutting the packaging units along the sawing street to form packaging structures.

18. The method of claim 17, wherein the first molding layer successively molds the based islands of the packaging units.

19. The method of claim 17, wherein the pin structures of the adjacent packaging units are isolated from each other by the sawing street and the second molding layer.

20. The method of claim 19, wherein the pin structures of the packaging units are arranged one by one on an outer circumference of the chips of the packaging units.
